(19) United States
(12) Patent Application Publication
(10) Pub. No.: US 2026/0037685 A1
(43) Pub. Date: Feb. 5, 2026

(54) METHOD AND APPARATUS FOR PROVIDING SIMULATIONS OF HYDROGEN REFILLING STATIONS

(71) Applicant: ANGI Energy Systems LLC, Janesville, WI (US)

(72) Inventors: Jonathan RAREY, Cornelius, NC (US); Jake BOKORNEY, McLeansville, NC (US); Trevor NASH, Edgerton, WI (US)

(21) Appl. No.: 18/792,030

(22) Filed: Aug. 1, 2024

(51) Int. Cl. G06F 30/20

(52) U.S. Cl. CPC G06F 30/20

(57) ABSTRACT

Providing computer simulations of a hydrogen refilling station (HRS) includes obtaining an HRS architecture file including architecture parameters and a demand profile file including demand parameters. When at least one variable parameter is present in the architecture or demand parameters, each of the variable parameters having a specified range of values and step size, a plurality of model instances is generated for each unique combination of values for the at least one variable parameter. Each of the plurality of model instances is provided to at least one processing device and, at each of the at least one processing device, the model instance is executed and an executed model instance and model results are returned. Upon completion of execution of plurality of model instances, at least a portion of the model results are compiled in an output file.

### FIELD

The present disclosure concerns computer simulations and, more particularly, methods and apparatus for providing simulations of hydrogen refilling stations.

### BACKGROUND

While demand for alternative fuel vehicles is expected to increase in coming years, the rate of growth for such vehicles is necessarily dependent upon the availability of fueling options for consumers. As the number of such options increases and therefore become more widely available, uptake of alternative fuel vehicles becomes easier and more attractive for consumers.

One significant option in the realm of alternative fuel vehicles are fuel cell electric vehicles (FCEVs), which typically rely on the use of pressurized hydrogen fuel and fuel cells for the pollution-free generation of electricity that, in turn, is used to power electric drive motors on FCEVs. The continued growth of FCEVs will be driven, in part, by the availability of hydrogen refilling stations (HRSs) in which hydrogen fuel is supplied to consumers in much the same manner that petroleum products (gasoline and diesel) are currently supplied to consumers owning internal combustion engine vehicles.

Petroleum-based refilling stations have been around for many decades such that their design and operation are well understood. In particular, initial capital and overhead costs for the construction and operation of such refilling stations are likewise readily ascertainable based on relatively few assumptions such as worst-case scenario demand profiles and number of fuel pumps. Additionally, because demand for such petroleum products is well understood given the many years of available data, it is fairly simple to determine the suitability of a given refilling station design to service the reasonably anticipated needs of an area in which refilling station construction is planned.

However, unlike petroleum-based refilling stations, experience with HRSs has been relatively short-lived, having only been developed over the last few years. For example, according to estimates, there are only 59 HRSs, as compared with approximately 150,000 petroleum refueling stations, in the United States as of 2023. As a result, developing an understanding of the initial capital and operational overhead costs is less predictable given the comparative dearth of relevant data. Further complicating such understanding is that delivery of hydrogen to FCEVs is generally more complex than delivery of petroleum products. For example, different fueling strategies may be required depending on the type of FCEV vehicles being serviced, which, in turn, may necessitate additional storage, compression and cooling equipment, not to mention additional plumbing and control equipment, necessary to successfully deliver hydrogen to consumers via end-point dispensers. Consequently, tools that would allow a variety of HRS designs to be accurately simulated prior to construction would be of significant benefit.

Such simulations tools currently exist, though their performance has room for improvement. For example, the National Renewable Energy Laboratory (NREL) has promulgated the so-called Hydrogen Station Capacity Evaluation (HySCapE) tool, which provides accurate modeling of hydrogen gas flows in proposed HRS architectures. However, only limited support of differing HRS architectures is provided by the HySCapE tool, and demand profile options are also limited. Furthermore, overly simple models of specific equipment types (e.g., compressors) and erroneous delivery simulation (e.g., lack of offload compressor simulation) causes decreased result accuracy.

Thus, an improved simulation tool that provides improved simulation capability for variable HRS architectures based on flexible demand profiles with increased modeling accuracy would be a welcome advancement in the art.

### SUMMARY

The instant disclosure describes techniques for providing simulations of hydrogen refilling stations that address the above-noted shortcomings. In an embodiment, a method of providing computer simulations of a hydrogen refilling station (HRS) comprises obtaining an HRS architecture file including architecture parameters specifying site delivery assets and configuration thereof, as well as obtaining a demand profile file including demand parameters specifying a number of vehicles, vehicle arrival times and vehicle types. When at least one variable parameter is present in the architecture parameters or the demand parameters, each of the variable parameters having a specified range of values and step size, the method further comprises, for each unique combination of values for the at least one variable parameter, as determined by the specified ranges of values and step sizes of the respective ones of the at least one variable parameter, generating a model instance based on the architecture parameters and the demand parameters including the combination of values for the at least one variable parameter to provide a plurality of model instances. Each of the plurality of model instances is provided to at least one processing device and, at each of the at least one processing device, the method further comprises executing the model instance and returning an executed model instance and model results. Upon completion of execution of plurality of model instances by the at least one processing device, at a portion of the model results are compiled in an output file.

A corresponding apparatus is also disclosed.

### BRIEF DESCRIPTION OF THE DRAWINGS

The foregoing and other features and advantages will be discussed in detail in the following non-limiting description of specific embodiments in connection with the accompanying drawings, in which:

FIG. 1 is a block diagram of a system in accordance with the instant disclosure;

FIG. 2 is a block diagram of a processing device that may be used to implement various aspects of the teachings of the instant disclosure;

FIG. 3 is a functional block diagram illustrating structure for implementing computer simulations of hydrogen refilling stations in accordance with the teachings of the instant disclosure;

FIG. 4 is a flowchart of processing in accordance with the instant disclosure; and

FIGS. 5A-5C are schematic block diagrams illustrating examples of HRS architectures.

### DETAILED DESCRIPTION OF THE PRESENT EMBODIMENTS

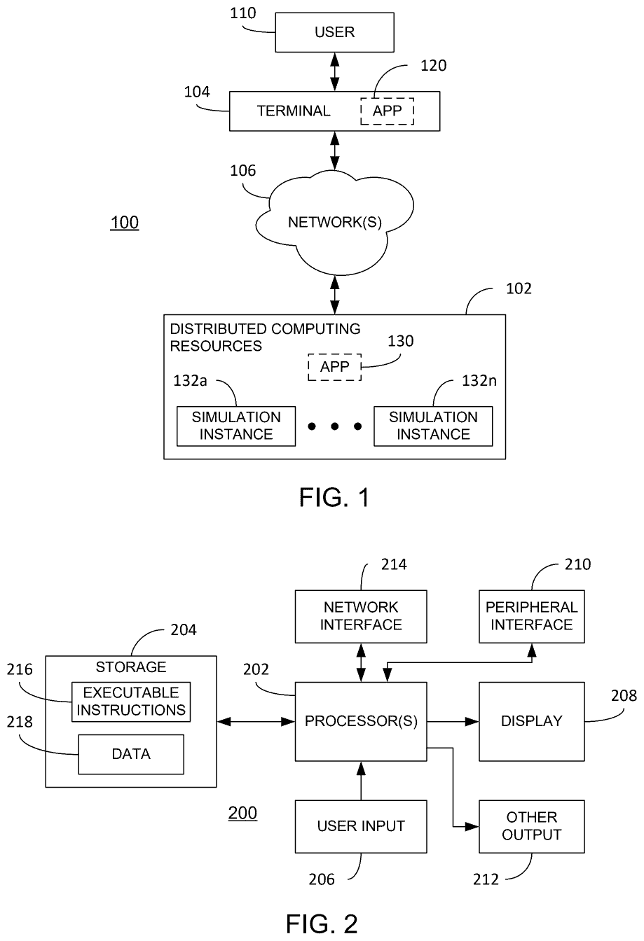

Referring now to FIG. 1, a system 100 in accordance with the instant disclosure is shown. Specifically, the system 100 comprises distributed computing resources 102 in communication with a plurality of terminals 104 (only one shown for ease of illustration) via one or more intervening networks 106. As described in greater detail below, the distributed computing resources 102 may comprise one or more server computers, database servers or other types of computing devices as known in the art, particularly in connection with, for example, the implementation of so-called cloud computing. Similarly, the terminal(s) 104 may comprise processing devices deployed for the use of individual users or small groups of individual users 110, such as desktop computers, laptop computers or the like. Although a single terminal 104 and user 110 is illustrated in FIG. 1, it is understood that a large number of terminals and users may be accommodated in the system of FIG. 1. The user 110 may be one or more people seeking to simulate a variety of HRS architectures based on varying demand profiles in order to assess initial capital and operating costs while still assuring desired performance of an HRS.

Regardless of their form, the terminals 104 or other computing devices used to communicate with the controller may employ well-known communication protocols (e.g., the Internet Protocol Suite or TCP/IP supporting HTTP) for this purpose. The network(s) 106 may comprise a public network (e.g., the Internet, World Wide Web, etc.) or private network (e.g., local area network (LAN), etc.) or combinations thereof (e.g., a virtual private network, LAN connected to the Internet, etc.). Furthermore, the network 106 need not be a wired network only, and may comprise wireless network elements as known in the art.

As shown, the terminal(s) 104 may implement a simulation application 120, which may comprise software instructions to be executed by the terminal(s) 104 to implement the simulation of HRSs, particularly the coordination of many multiple instances 132a-132n of HRS simulations, as described in detail below. As further described below, the distributed computing resources 102 implement execution of the multiple simulation instances 132a-132n based on inputs received from the one or more terminals 104. In an alternative embodiment, the simulation application 130 may instead be implemented within the distributed computing resources 102, with only relevant inputs being provided from the terminal(s) 104 to the simulation application 130. As used herein, an “instance” or “instantiation” refers to the creation, by a computing device within the distributed computing resources 102, of a new context or copy of a model (i.e., based on unique inputs to and/or unique configuration of the pre-existing model) that may be subsequently executed by the computing device so as to obtain outputs determined through execution of the model in that new context. As noted above, the distributed computing resources 102 may be implemented by those having skill in the art using a cloud computing platform such as the “AWS” Lambda computing platform provided by Amazon Web Services, Inc.

Referring now to FIG. 2, a representative processing device 200 that may be used to implement the teachings of the instant disclosure is illustrated. The device 200 may be used to implement, for example, the various processing or computing devices noted above concerning the distributed computing resources 102 and terminal(s) 104. Regardless, the device 200 comprises a processor 202 coupled to a storage component 204. The storage component 204, in turn, comprises stored executable instructions 216 and data 218. In an embodiment, the processor 202 may comprise one or more of a microprocessor, microcontroller, digital signal processor, co-processor or the like or combinations thereof capable of executing the stored instructions 216 and operating upon the stored data 218. Likewise, the storage component 204 may comprise one or more devices such as volatile or nonvolatile memory including but not limited to random access memory (RAM) or read only memory (ROM). Furthermore, the storage component 204 may be embodied in a variety of forms, such as a hard drive, optical disc drive, floppy disc drive, etc. Processor and storage arrangements of the types illustrated in FIG. 2 are well known to those having ordinary skill in the art. In one embodiment, the processing techniques described herein (i.e., the simulation application 120, 130 and/or simulation instances 132a-132n) are implemented as a combination of executable instructions and data within the storage component 204.

As shown, the device 200 may comprise one or more user input devices 206, a display 208, a peripheral interface 210, other output devices 212 and a network interface 214 in communication with the processor 202. The user input device 206 may comprise any mechanism for providing user input to the processor 202. For example, the user input device 206 may comprise a keyboard, a mouse, a touch screen, microphone and suitable voice recognition application or any other means whereby a user of the device 200 may provide input data to the processor 202. The display 208, may comprise any conventional display mechanism such as a cathode ray tube (CRT), flat panel display, or any other display mechanism known to those having ordinary skill in the art. The peripheral interface 210 may include the hardware, firmware and/or software necessary for communication with various peripheral devices, such as media drives (e.g., magnetic disk or optical disk drives), other processing devices or any other input source used in connection with the instant techniques. Likewise, the other output device(s) 212 may optionally comprise similar media drive mechanisms, other processing devices or other output destinations capable of providing information to a user of the device 200, such as speakers, LEDs, tactile outputs, etc. Finally, the network interface 214 may comprise hardware, firmware and/or software that allows the processor 202 to communicate with other devices via wired or wireless networks, whether local or wide area, private or public, as known in the art. For example, such networks may include the World Wide Web or Internet, or private enterprise networks, as known in the art.

While the device 200 has been described as one form for implementing the techniques described herein, those having ordinary skill in the art will appreciate that other, functionally equivalent techniques may be employed. For example, as known in the art, some or all of the functionality implemented via executable instructions may also be implemented using firmware and/or hardware devices such as application specific integrated circuits (ASICs), programmable logic arrays, state machines, etc. Furthermore, other implementations of the device 200 may include a greater or lesser number of components than those illustrated. Once again, those of ordinary skill in the art will appreciate the wide number of variations that may be used is this manner. Further still, although a single processing device 200 is illustrated in FIG. 2, it is understood that a combination of such processing devices may be configured to operate in conjunction (for example, using known networking techniques) to implement the teachings of the instant disclosure.

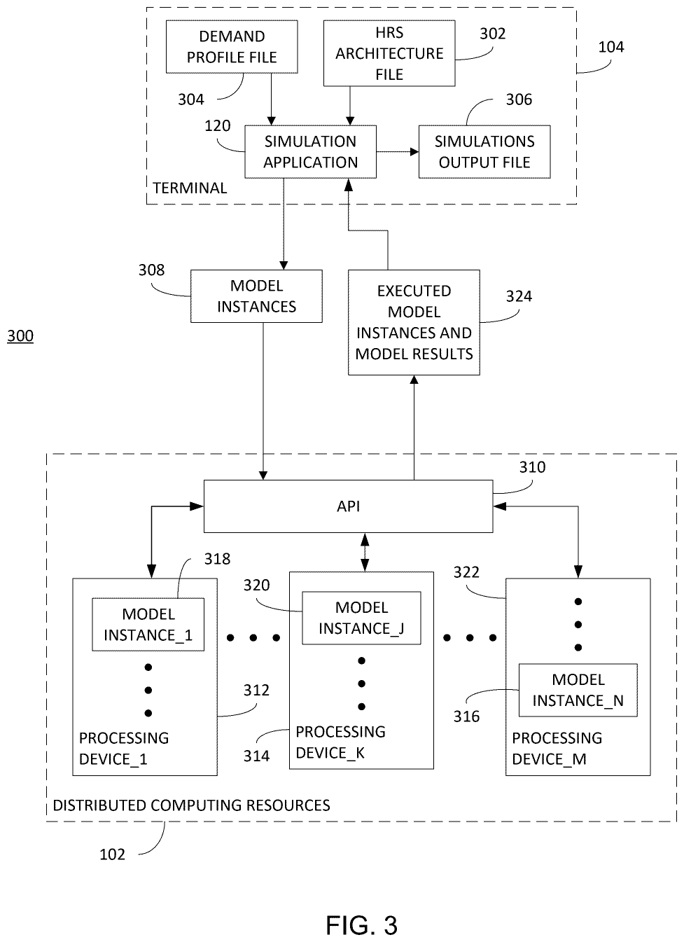

A functional block diagram of structure for implementing computer simulations of hydrogen refilling stations in accordance with the teachings of the instant disclosure is further illustrated with respect to FIG. 3. Similar to FIG. 1, FIG. 3 illustrates a terminal 104 in communication with distributed computing resources 102. In an embodiment, the terminal 104 may implement a simulation application 120 that receives an HRS architecture file 302 and a demand profile file 304 as well as executed model instances and model results 324 as inputs and provides model instances 308 as output, as well as a simulations output file 306. In an embodiment, both the HRS architecture file 302 and the demand profile file 304 are text based documents provided to the simulation application 120 by a user of the terminal 104. Such files 302, 304 may be created by the user using conventional text editing software.

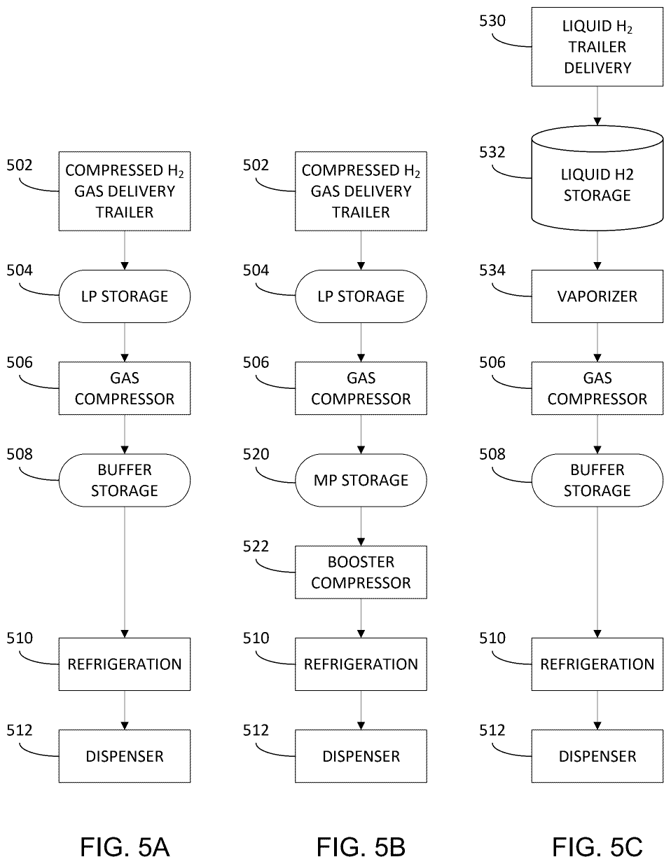

The HRS architecture file 302 sets forth architecture parameters specifying components of the HRS site used to achieve hydrogen delivery and configuration of such components relative to each other. FIGS. 5A-5C illustrates various examples of potential HRS site configurations. Each of the components illustrated in FIGS. 5A-5C are known to those of skill in the art.

In the example of FIG. 5A, a compressed hydrogen gas delivery trailer 502 (e.g., a tube trailer) delivers compressed hydrogen to the HRS site, which hydrogen is then stored in a low pressure storage tank 504. As needed, hydrogen gas is drawn from the low pressure storage tank 504 and pressurized by a gas compressor 506, which outputs the relatively highly pressurized hydrogen gas to a buffer storage tank 508. When hydrogen delivery is required at a dispenser 512, sufficiently pressurized hydrogen gas is drawn from the buffer storage tank 508, which event may cause, in turn, further transfer of pressurized hydrogen gas from the low pressure storage tank 504 to the buffer storage tank 508 in order to replace the used hydrogen gas and to restore proper pressure in the buffer storage tank 508. However, as known in the art, the pressurization process heats up the hydrogen gas, which must nevertheless be dispensed at a lower temperature given the requirements of current FCEVs, for example. Thus, a refrigeration unit 510 is disposed between the buffer storage tank 508 and dispenser 512 in order to sufficiently cool the hydrogen gas as required for delivery through the dispenser 512.

Such refrigeration additionally addresses the well-known reverse Joule-Thompson effect of hydrogen. Typically, when a gas (such natural gas and CO2 for instance) is depressurized after passing through a restriction such as a valve, the gas will cool rapidly. On the other hand, hydrogen, in most environments, heats up as it depressurizes through a valve. In the case of hydrogen fuel systems, such heating occurring at the point of delivery could contributed to heating of a vehicle's fuel tank, which in turn could lead to premature (and potentially catastrophic) fuel tank failure. To minimize this risk, the cooling effect of the refrigeration unit 510 (e.g., down to as low as −40° C.) helps counteract such heating, thereby reducing vehicle tank heating.

The example of FIG. 5B is substantially similar to the example of FIG. 5A, with the exception that the buffer storage tank 508 in FIG. 5A is replaced with a medium pressure storage tank 520 and a booster compressor 522, i.e., in a so-called cascade configuration that provides efficiencies in certain circumstances. In this case, the hydrogen gas from the low pressure storage tank 504 is pressurized by the compressor 506 to a lesser level as compared to the buffer storage 508 in FIG. 5A. As delivery demands are made, hydrogen gas is drawn from the medium pressure storage tank 520 and further pressurized by the booster compressor 522 to the required pressure for delivery by the dispenser 512.

Further still, the example of FIG. 5C is substantially similar to the example of FIG. 5A with the exception that the delivery trailer 502 and low pressure storage tank 504 are replaced with a liquid hydrogen delivery trailer 530, liquid hydrogen storage tank 532 and a vaporizer 534. Whereas the embodiments of FIGS. 5A and 5B are best suited to low-to medium-volume HRSs (in terms of anticipated demand), the embodiment of FIG. 5C is better suited for larger volume HRSs. In this case, the liquid hydrogen delivery trailer 530 is able to deliver comparatively large quantities of liquid hydrogen, which is then maintained at the appropriate temperature and pressure to maintain its liquid state in the liquid hydrogen storage tank 532. When required to supply hydrogen gas to the buffer storage tank 508, the vaporizer 534 is employed to convert a quantity of liquid hydrogen into a gaseous form that is then pressurized by the compressor 506 and further processed as described above.

In keeping with HRS architecture examples shown in FIG. 5A-5C, the HRS architecture file 302 includes listings of every component in the HRS design related to the transfer of hydrogen, their relevant interconnections and, where applicable, to the specifications of such components as they relate to the transfer of hydrogen. An example of a HRS architecture file is set forth in Table 1 below.

TABLE 1
# flow rates in kg/min
# mass in kg
# pressure in Bar
[HRS]
line_pres_drop_bar = 50
# 300 bar trailer
[Cascade Bank 1]
name = “Trailer”
vol_L = 48000
temp_C = 20
pres_B = 300
target_pres_B = 300
[Compressor 1]
# variable compressor types
type = PDC-13-2000/7500(100), PDC-13-3500/7500(100),
PDC-13-4500/7500(100)
inlet_connection = Cascade Bank 1
outlet_connection = Cascade Bank 2, Cascade Bank 3, Cascade Bank 4,
Cascade Bank 5
has_precooler = True
coolant_temp_f = 50
[Cascade Bank 2]
name = “Mid Pressure Storage 1”
# volume ranges is [1189]
vol_1_min = 1189
vol_1_step_size = 1189
vol_1_n_steps = 1
temp_c = 20
pres_b = 450
target_pres_b = 450
[Cascade Bank 3]
name = “Mid Pressure Storage 2”
# volume ranges is [5945, 8323, 10701]
vol_1_min = 5945
vol_1_step_size = 2378
vol_1_n_steps = 3
temp_c = 20
pres_b = 450
target_pres_b = 450
[Cascade Bank 4]
name = “Mid Pressure Storage 3”
# volume ranges is [5945, 8323, 10701]
vol_1_min = 5945
vol_1_step_size = 2378
vol_1_n_steps = 3
temp_c = 20
pres_b = 450
target_pres_b = 450
[Valve Panel 1]
dispensers = Dispenser 1, Dispenser 2
cascade_banks = Cascade Bank 2, Cascade Bank 3, Cascade Bank 4,
Cascade Bank 1
[Dispenser 1]
sides = 1
total_h35_nozzles = 1
total_h50_nozzles = 0
total_h70_nozzles = 0
flow_rate = 3.6
delay_time = 180
[Dispenser 2]
sides = 1
total_h35_nozzles = 1
total_h50_nozzles = 0
total_h70_nozzles = 0
flow_rate = 3.6
delay_time = 180

An initial value denoted “line_pres_drop_bar” indicates an optional valve used to represent a static pressure drop in the tubing, hosing, valving and fittings in the system used to supply the hydrogen to the vehicle. This value is useful in roughly accounting for long conduit lines and various pressure drops that are typically inherent to an HRS.

Further the example of Table 1, hydrogen is supplied to the refilling station via a so-called tube trailer denoted as “Cascade Bank 1” having a volume of 48,000 liters and storing hydrogen gas at an initial temperature of 20° C. and an initial pressure of 300 bar. A compressor, denoted “Compressor 1,” is specified, in this example, as any one of three diaphragm-type compressors supplied by PDC Machines LLC that includes a pre-cooler functionality as known in the art. Compressor 1 has an inlet coupled to Cascade Bank 1 and an outlet coupled to multiple cascade banks (“Cascade Bank 2,” “Cascade Bank 3,” “Cascade Bank 4” and “Cascade Bank 5”), where the order of the connected banks corresponds to the order in which they will be filled, i.e., Cascade Bank 2 has highest priority and will be filed first, followed by Cascade Bank 2, etc. Similar to Compressor 1, Cascade Bank 3 and Cascade Bank 4 in this example are each specified as being variable in their configurations. Specifically, both Cascade Bank 3 and Cascade Bank 4 are indicating as having a minimum size of 5,945 liters ranging up to 10,701 liters in up to three steps based on a 2,378 liter step size meaning, in effect, that these cascade banks may each have volumes of 5,945, 8,323 or 10,701 liters. It is noted that, while Cascade Bank 2 is similarly defined according to a minimum size, number of steps and step size, the designation of only a single step and a step size equal to the minimum size indicates that Cascade Bank 2 is only capable, in this example, of having a volume of 1,189 liters.

The HRS architecture file 302 in the example of Table 1 further defines the use of “Valve Panel 1,” “Dispenser 1” and “Dispenser 2.” Both Dispenser 1 and Dispenser 2 are hydrogen dispensing systems used to effectuate the last step in transferring compressed hydrogen from the HRS to a vehicle. In this example, both Dispenser 1 and Dispenser 2 are each configured to have one nozzle capable of delivering hydrogen pressurized up to 35 MPa (350 Bar) at an flow rate of 3.6 kg/min and a delay time, i.e., the time required between filling events to account for user actions (exiting/entering a vehicle, coupling/decoupling the dispenser to the vehicle, attending to payment, etc.), of 180 seconds. Finally, “Valve Panel 1” represents a valve panel (such as those provided by ANGI Energy Systems Inc.) configured to route pressurized hydrogen gas between various elements in the HRS in either an autonomous or remotely controlled manner. Thus, in the example of Table 1, Valve Panel 1 is configured to route hydrogen received from any of Cascade Bank 2, Cascade Bank 3, Cascade Bank 4, Cascade Bank 1 (preferably, in that order) and route it to Dispenser 1 and/or Dispenser 2.

In a similar vein, the demand profile file 304 specifies a number of vehicles being serviced in the simulation, the types of each vehicle as well as their arrival times. An example of a demand profile file is set forth in Table 2 below.

TABLE 2

[Demand Parameters]
# profile = one hour
# profile = three hour
profile = n hour
# profile = Chevron Friday
# profile = custom
[n Hour]
n = 14
# start hour of 0 is 12AM, 12 is 12PM, 23 is 11PM, etc.
start_hour = 6
vehicles_per_hour = 2
vehicle_desc = Light Duty H70
tank_size_1 = 126
tank_temp_c = 20
init_tank_pres_bar = 100
target_tank_pres_bar = 700
# input time
# 0 12AM
# 1 1AM
# 2 2AM
# ...
# 12 12PM
# 13 1PM
# 14 2PM
# 15 3PM
# 16 4PM
# 17 5PM
# 18 6PM
# 19 7PM
# 20 8PM
# 21 9PM
# 22 10PM
# 23 11PM
# 24 12AM
[Chevron Friday]
total_demand = 1200
n_days = 1
vehicle_desc = Light Duty H70
tank_size_1 = 126
tank_temp_c = 20
init_tank_pres_bar = 100
target_tank_pres_bar = 737
[Custom]
[Vehicle 1]
name = Light Duty H70
arrival_time = 01:00:00
tank_size_1 = 150
tank_temp_c = 20
init_tank_pres_bar = 100
target_tank_pres_bar = 700
[Vehicle 2]
name = Light Duty H70
arrival_time = 01:00:00
tank_size_1 = 150
tank_temp_c = 20
init_tank_pres_bar = 100
target_tank_pres_bar = 700

Table 2 describes the simulated vehicles to arrive at the simulated HRS. Each simulated vehicle has parameters which determine how the vehicle will be filled, and when the vehicle will arrive at the site. Each simulated vehicle's hydrogen storage tank size in liters “tank_size_l”, the vehicle's initial tank temperature in Celsius when it arrives at the station “tank_temp_c”, the vehicle's initial tank pressure in Bar “init_tank_pres_bar” and the vehicle's desired final tank pressure in Bar “target_tank_pres_bar” are all used to determine how the HRS will attempt to fill each simulated vehicle. Optional values are also allowed, such as “dispenser_group_name” which allows the user to associate specific vehicles to dispensers which have this matching parameter. This feature is commonly used to separate public and privately owned vehicles and only allow them to fill at specific dispenser groups. Further, a description for the vehicle described is useful for analysis.

Beyond describing the unique vehicle parameters, this table also shows a series of demand profile types that these vehicles can be associated with. The allowed options are “one hour”, “three hour”, “n hour”, “Chevron Friday” and “custom”. Selection of the one “one hour” parameter allows the user to define a set number of vehicles to arrive within a given hour. Similarly, selection of the “three hour” parameter allows the user to define a set number of vehicles to arrive within a given three hours, whereas selection of the “n hour” parameters allows the user to define a set number of vehicles to arrive within a specified number of hours. The “Chevron Friday” parameter is a unique demand profile which describes the hourly station demand each hour of the day for a refueling station on it's busiest day, e.g., Friday. This demand profile is scaled by the number of total kilograms that the user wishes to simulate for that day, or days. The “Custom” parameter allows the user to build a completely customized demand profile by building a list of vehicles which can all have different vehicle parameters as well as arrival times.

The system can load multiple of these demand profiles at a time. This feature allows the user to quickly and accurately build complex demand profiles that might otherwise require significant time to describe.

A feature of the instant disclosure is the ability to cause multiple instantiations of a model according to one or more parameters in the HRS architecture file 302 and/or the demand profile file 304 defined as variable parameters. In the examples above, specifically Table 1, Compressor 1, Cascade Bank 3 and Cascade Bank 4 are each defined as being capable of taking any of three different values. Notably, whereas Cascade Bank 3 and Cascade Bank 4 are each defined according to three different numerical values representative of their potential respective volumes, Compressor 1 is defined according to three different model designations being representative of different performance capabilities of the compressor. As described below, the presence of such variable parameters in the HRS architecture file 302 and/or the demand profile file 304 permit the rapid generation of a sizable number of models (e.g., hundreds or even thousands) such that a user is able to investigate a wide variety of scenarios. This ability is particularly important when it is appreciated that discovery of best-case system design typically requires changing parameters (compressors, storage volumes, etc.) and testing each change to see how the result has changed. With the ability to quickly generate large numbers of tests spanning a wide combination of potential parameter values, the techniques described herein facilitate comparison of scenarios resulting in the simpler, quicker and more accurate selection of a best-case system.

With reference once again to FIG. 3, the simulation application 120 parses the HRS architecture file 302 and demand profile file 304 and generates the plurality of model instances 308, particularly based on the presence of any variable parameters specified in the HRS architecture file 302 and/or demand profile file 304. That is, the simulation application 120 will create a separate model for at least some of (preferably all of) the possible permutations defined by the variable parameters. For example, based on the variable parameters defined in Table 1 above, where there are three types of compressors assigned to a single compressor, and two storage banks each with a range of three volumes, there will be 3·3·3=3³=27 total models generated. As will be appreciated by those skilled in the art, the number of models generated generally increases proportionally to the number of possible values for each variable parameter, and exponentially with each additional variable parameter. For this reason, and appreciating that the time and resources required to execute all of the generated model instances 308 increase as the total number of generated model instances 308 increases, the user 110 should attempt to determine roughly what the number and respective ranges of variable parameters should be in order to ensure that too many models are not created.

As will be appreciated by those skilled in the art, each model instance 308 includes mathematical representations of the state and/or operation of each component listed in the HRS architecture file 302 at various points in time taking into account the interrelationships of such components (i.e., inputs/outputs between such components) and the demands placed upon them according to the demand profile file 304. Thus, in accordance with known techniques, the specifications set forth in the HRS architecture file 302 dictate the order in which each component is updated for each time increment and based on the occurrence of demands placed upon the system according to the demand profile file 304.

The plurality of model instances 308 generated by the simulation application 120 are provided to (i.e., transmitted via one or more intervening networks, not shown) to the distributed computing resources 102 for execution. For example, where the distributed computing resources 102 are embodied by a cloud computing resource such as “AWS” Lambda, this is accomplished by the simulation application 120 communicating with an application programming interface (API) 310 implemented by the distributed computing resources 102. In this case, each model instance is passed to the API 310 via a function call by the simulation application 120. Without any further involvement by the simulation application 120, the API 310 is able to allocate the necessary resources (i.e., processing devices 312-316 as shown in FIG. 3) for execution of each model instance. As known in the art, this implies that various model instances 318-322 may be distributed across multiple processing devices within the context of the distributed computing resources 102. This is illustrated in FIG. 3 in which N different model instances are distributed across M different processing devices 312-316, with the possibility that one or more model instances 318-322 may be executed by any given processing device (using, for example, concurrent, multi-core processing as known in the art).

Regardless, as model instances 318-322 are executed, each of the executed model instances and corresponding model results 324 are returned by the API 310 to the simulation application 120. In a presently preferred embodiment, execution of each model is a second-by-second update of the state of each model component in terms of various relevant operational parameters, e.g., on/off, total stored mass (kg), flow rate, etc. Execution of each model is considered complete once the specified entire time interval to be simulated (e.g., 8 hours, 12 hours, etc.) has been reached. Although second-by-second execution of each model is presently preferred, it is be appreciated that greater (i.e., sub-second time increments) or lesser (i.e., multiple second time increments) frequencies could be equally employed to achieve greater or lesser system performance resolution.

As used herein, the model results are values of one or more specific parameter for a given model instance, where the specific parameters are representative of a desired performance characteristic for the HRS designs under consideration. For example, a key performance indicator for HRSs is mean fill time, i.e., the average amount of time it takes to complete a refill operating according to a given model instance. Furthermore, the model results may include design parameter values that may be used to distinguish one model instance from another. Thus, for example, the model results may include indication of storage tank volumes for key components. Table 3 below illustrates an example of such model results (it being appreciated that only a small number of results are shown for ease of illustration and that, in practice, such results could likely include hundreds or even thousands of rows corresponding to separate mode instantiations).

TABLE 3

| | | Cascade | Cascade | Mean | Fill |
|---|---|---|---|---|---|
| Model | | Bank 1 | Bank 2 | Fill | Time |
| Number | Result | Vol (L) | Vol (L) | Time | Std Dev |
| 22 | PASS | 500 | 1000 | 0:03:57 | 49.167 |
| 23 | PASS | 500 | 1250 | 0:03:57 | 49.157 |
| 24 | PASS | 500 | 1500 | 0:03:57 | 49.157 |
| 9 | PASS | 200 | 1500 | 0:03:58 | 49.584 |
| 12 | PASS | 300 | 1000 | 0:03:59 | 50.027 |
| 8 | PASS | 200 | 1250 | 0:04:00 | 50.691 |
| 16 | PASS | 400 | 750 | 0:04:00 | 50.442 |
| 20 | PASS | 500 | 500 | 0:04:04 | 52.330 |
| 11 | PASS | 300 | 750 | 0:04:06 | 53.109 |
| 4 | PASS | 100 | 1500 | 0:04:07 | 54.483 |
| 7 | PASS | 200 | 1000 | 0:04:08 | 53.975 |

In the example of Table 3, the results are sorted by mean fill time from least to greatest. In this case, model numbers 22-24 are characterized by having a first cascade bank (hydrogen storage) having a volume of 500 liters, whereas model number 22 has a second cascade bank having volume of 1000 liters, model number 23 has a second cascade bank having volume of 1250 liters and model number 24 has a second cascade bank having volume of 1500 liters. As further shown, each of these models (instantiations) result in a simulated average fill time of 3 minutes, 57 seconds with nearly identical fill time standard deviations. With this information, a user may infer, for example, that any of model numbers 22-24 meet a desired average fill time (e.g., under 4 minutes), and that model number 22 is preferable because it relies on the least amount of total cascade bank volume (being indicative of lower capital cost for such cascade banks). Alternatively, a use may infer that model number 24 is preferable to the extent that the availability of increased cascade bank volume indicates the potential to adequately service a more challenging demand profile.

It is once again noted that, while the simulation application 120 is depicted as being implemented by the terminal 104, it is appreciated that some or all of its functionality could be implemented in combination with, or even entirely by, computing resources provided by the distributed computing resources 102, with only the HRS architecture file 302 and demand profile file 304 being provided by the terminal 104 to the API 310.

The ability to create and simultaneously run a large number of model instances as described herein provides significant improvement in the ability to quickly identify best case design scenarios, which can in turn lead to more rapid development and design innovation. For example, a typical laptop may be able to simultaneously utilize 12 central processing unit (CPU) cores to execute model instances. In comparison, use of distributed computing resources as described above can lead to 1,000 times that number of CPU cores being used to simultaneously execute model instances. In testing, such increased computing availability resulted in up to a 101 times faster execution of model instances. As a result, simulations that would have required 2 days to execute in a single laptop environment can instead be completed in as little as 30 minutes. Stated another way, a typical simulation runtime of 45 minutes on a laptop can be reduced to about 30 seconds using the distributed computing environment illustrated in FIG. 3. Again, such significant improvement in throughput allows the correspondingly quicker determination of best case design scenarios and further development of potentially improved systems.

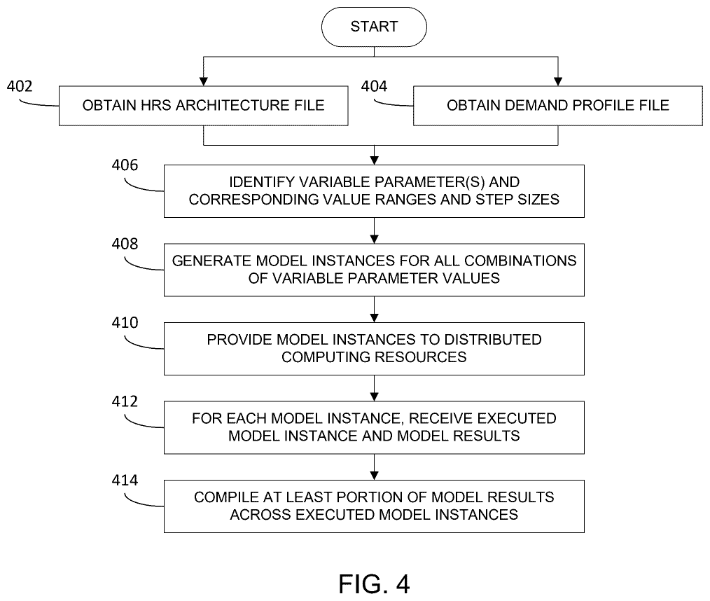

Referring now to FIG. 4, a flowchart illustrating processing in accordance with the instant disclosure is shown. Specifically, the processing shown in FIG. 4 may be implemented by the simulation application 120, 130 as described above. Thus, at block 402, the simulation application obtains an HRS architecture file and, at block 404, the simulation application obtains a demand profile file. Note that, while blocks 402 and 404 are illustrated as occurring simultaneously, this is not a requirement and such files could be obtained in a sequential manner. As used herein, the step of “obtaining” includes a passive implementation in which the noted files are provided to and received by the simulation application at the instigation of a user/requester external to the simulation application, or an active implementation in which the simulation application seeks out, requests and receives such files from a source as part of its execution.

Regardless, once the HRS architecture and demand profile files have been obtained, processing continues at block 406 in which the occurrence of one or more variable parameters in the HRS architecture and/or demand profile files is identified. As used herein, a variable parameter is a parameter that is defined within its file as being capable of varying across a range of values in accordance with a given step size. For example, a gas compressor may be specified as being able to output pressurized hydrogen at a flow rate varying from 0.8-2.4 kg/min, in increments of 0.1 kg/min. In this example, this implies that the flow rate parameter for this compressor may take on 17 distinct values (inclusive of the range endpoints). As will be appreciated by those skilled in the art, a wide variety of parameters and corresponding ranges and steps sizes may be designated in this manner dependent upon the nature of the parameter.

At block 408, the simulation application generates a plurality of model instances based on all combinations of the variable parameter values. For example, a given pair of HRS architecture and demand profile files may include three variable parameters, P1, P2 and P3 with value range and step sizes such that P1 may assume 10 distinct values, P2 may assume 5 distinct values and P3 may assume 15 distinct values. In this case, a total of 10·5·15=750 total combinations of values for variable parameters P1, P2 and P3 are possible. Thus, at block 408, a total of 750 models are instantiated by the simulation application, which model instances are then provided to the distributed computing resources at block 410. However, though less preferred, it is also possible that less than the total number of possible model instances (i.e., less than 750 in this example) could be instantiated by the simulation application.

As described above, the plurality of model instances are then executed by the distributed computing resources and then, at block 412, the simulation application receives an executed model instance and model results for models instance provided at block 410. Thereafter, at block 414, at least a portion of the model results obtained at block 412, across all model instances, are compiled into an output file, which may take the form of tabular results as exemplified in Table 3 above.

What is claimed is:

1. A method of providing computer simulations of a hydrogen refilling station (HRS), the method comprising:
obtaining an HRS architecture file including architecture parameters specifying site delivery assets and configuration thereof;
obtaining a demand profile file including demand parameters specifying a number of vehicles, vehicle arrival times and vehicle types;
when at least one variable parameter is present in the architecture parameters or the demand parameters, each of the variable parameters having a specified range of values and step size:
for each unique combination of values for the at least one variable parameter, as determined by the specified ranges of values and step sizes of the respective ones of the at least one variable parameter, generating a model instance based on the architecture parameters and the demand parameters including the combination of values for the at least one variable parameter to provide a plurality of model instances;
providing each of the plurality of model instances to at least one processing device and, at each of the at least one processing device:
executing the model instance;
returning an executed model instance and model results; and
upon completion of execution of plurality of model instances by the at least one processing device, compiling at a portion of the model results in an output file.
